(19) United States
(12) Patent Application Publication
(10) Pub. No.: US 2025/0364390 A1
(43) Pub. Date: Nov. 27, 2025

(54) SEMICONDUCTOR DEVICE AND METHOD OF MANUFACTURING SAME

(71) Applicant: SUMITOMO ELECTRIC DEVICE INNOVATIONS, INC., Kanagawa (JP)

(72) Inventor: Shingo INOUE, Kanagawa (JP)

(21) Appl. No.: 19/189,956

(22) Filed: Apr. 25, 2025

(30) Foreign Application Priority Data
May 23, 2024 (JP) 2024-084357

(51) Int. Cl. H01L 23/498; H01L 21/48; H01L 21/56; H01L 23/00; H01L 23/31

(52) U.S. Cl. CPC H01L 23/49838; H01L 21/4846; H01L 21/56; H01L 23/3121; H01L 24/32; H01L 24/48; H01L 24/49; H01L 24/73; H01L 2224/32225; H01L 2224/48225; H01L 2224/49175; H01L 2224/73265; H01L 2924/1815

(57) ABSTRACT

A semiconductor device includes a base having an upper surface, at least the upper surface being made of metal; one or more components that are mounted on the base with a first conductive member interposed between the one or more components and the base and includes a semiconductor chip; a second conductive member that is provided on the base and contains a sintered metal or a metal powder-containing resin and on which the one or more components are not mounted; a resin sealing portion that is provided over the base in contact with the base, the one or more components, and the second conductive member to seal the one or more components. The second conductive member is separated from the first conductive member.

### CROSS REFERENCE TO RELATED APPLICATIONS

This application is based on and claims priority to Japanese Patent Application No. 2024-084357 filed on May 23, 2024, the entire contents of which are incorporated herein by reference.

### TECHNICAL FIELD

The present disclosure relates to a semiconductor device and a method of manufacturing the same.

### BACKGROUND

It is known that a semiconductor chip is mounted on a base and the semiconductor chip is sealed with a resin. There are known techniques of roughening a surface of the base, of roughening some regions of the surface of the base where the semiconductor chip is not mounted, and of not providing a plating layer in a region of the surface of the base where the semiconductor chip is not mounted (for example, Japanese Unexamined Patent Application Publication No. 2010-287741, Japanese Unexamined Patent Application Publication No. 2010-161098, and Japanese Unexamined Patent Application Publication No. 2018-085480).

### SUMMARY

An embodiment according to the present disclosure is a semiconductor device including a base having an upper surface, at least the upper surface being made of metal; one or more components that are mounted on the base with a first conductive member interposed between the one or more components and the base and includes a semiconductor chip; a second conductive member that is provided on the base and contains a sintered metal or metal powder-containing resin and on which the one or more components are not mounted; and a resin sealing portion that is provided over the base in contact with the base, the one or more components, and the second conductive member to seal the one or more components. The second conductive member is separated from the first conductive member.

An embodiment according to the present disclosure is a semiconductor device including a base having an upper surface, at least the upper surface being made of metal; one or more components that are mounted on the base with a first conductive member interposed between the one or more components and the base and includes a semiconductor chip; a second conductive member that is provided on the base and contains a sintered metal or metal powder-containing resin and on which the one or more components are not mounted; and a resin sealing portion that is provided over the base in contact with the base, the one or more components, and the second conductive member to seal the one or more components. The second conductive member is connected to the first conductive member and is separated from the one or more components by a distance greater than or equal to a sum of a thickness of the first conductive member between the semiconductor chip and the base and a thickness of the semiconductor chip.

An embodiment according to the present disclosure is a method of manufacturing a semiconductor device. The method includes forming a first conductive member and a second conductive member on a base having an upper surface, at least the upper surface being made of metal; mounting one or more components including a semiconductor chip on the first conductive member and not mounting the one or more components on the second conductive member after the forming the first conductive member and the second conductive member; and forming a resin sealing portion over the base so as to be in contact with the base, the one or more components, and the second conductive member and seal the one or more components. The second conductive member is separated from the first conductive member or connected to the first conductive member, and separated from the one or more components by a distance greater than or equal to a sum of a thickness of the first conductive member between the semiconductor chip and the base and a thickness of the semiconductor chip.

### BRIEF DESCRIPTION OF THE DRAWINGS

FIG. 1 is a plan view of a semiconductor device according to a first embodiment.

FIG. 2 is a cross-sectional view taken along line A-A in FIG. 1.

FIG. 3 is a flowchart illustrating a method of manufacturing the first embodiment.

FIG. 4A is a plan view of a conductive member 18 in the first embodiment.

FIG. 4B is a plan view of conductive member 18 in the first embodiment.

FIG. 4C is a plan view of conductive member 18 in the first embodiment.

FIG. 5A is a cross-sectional view of conductive member 18 in the first embodiment.

FIG. 5B is a cross-sectional view of conductive member 18 in the first embodiment.

FIG. 5C is a cross-sectional view of conductive member 18 in the first embodiment.

FIG. 6A is a plan view illustrating another example of conductive member 18 in the first embodiment.

FIG. 6B is a cross-sectional view taken along line A-A in FIG. 6A.

FIG. 6C is a cross-sectional view illustrating still another example of conductive member 18 in the first embodiment.

FIG. 7A is a plan view illustrating still another example of conductive member 18 in the first embodiment.

FIG. 7B is a cross-sectional view taken along line A-A in FIG. 7A.

FIG. 8 is a plan view of a semiconductor device according to a second embodiment.

FIG. 9 is a cross-sectional view taken along line A-A in FIG. 8.

FIG. 10 is a circuit diagram of paths 50 and 52 in the second embodiment.

FIG. 11 is a plan view of a semiconductor device according to a first modification of the second embodiment.

FIG. 12 is a plan view of a semiconductor device according to a second modification of the second embodiment.

FIG. 13 is a plan view of a semiconductor device according to a third modification of the second embodiment.

FIG. 14 is a plan view of a semiconductor device according to a fourth modification of the second embodiment.

FIG. 15 is a circuit diagram of paths 50 and 52 in the fourth modification of the second embodiment.

FIG. 16 is a plan view of a semiconductor device according to a fifth modification of the second embodiment.

FIG. 17 is a circuit diagram of paths 50 and 52 in the fifth modification of the second embodiment.

FIG. 18 is a plan view of a semiconductor device according to a sixth modification of the second embodiment.

FIG. 19 is a circuit diagram of paths 50 and 52 in the sixth modification of the second embodiment.

### DETAILED DESCRIPTION

The adhesion between a metal surface of a base and a resin, which is a main component of a resin sealing portion, is low. For this reason, the resin sealing portion may peel off from the base due to a difference in linear expansion coefficient between the base and the resin sealing portion. Roughening the surface of the base can improve the adhesion between the base and the resin sealing portion. Furthermore, the adhesion between the base and the resin sealing portion can be improved by not providing a layer having a poor adhesion to the resin sealing portion in some regions. However, in a case where the entire surface of the base is roughened, when the roughening is increased to improve the adhesion, it is difficult to mount the semiconductor chip. In a case where a region in which the semiconductor chip is not mounted is roughened or the layer having a poor adhesion is not provided, a mounting region of the semiconductor chip is limited, reducing the flexibility in design.

According to the present disclosure, the adhesion between a base and a resin sealing portion can be improved.

### Description of Embodiments of the Present Disclosure

First, embodiments of the present disclosure will be listed and described.
(1) An embodiment of the present disclosure is a semiconductor device including a base having an upper surface, at least the upper surface being made of metal; one or more components that are mounted on the base with a first conductive member interposed between the one or more components and the base and include a semiconductor chip; a second conductive member that is provided on the base and contains a sintered metal or a metal powder-containing resin and on which the one or more components are not mounted; and a resin sealing portion that is provided over the base and is in contact with the base, the one or more components, and the second conductive member to seal the one or more components. The second conductive member is separated from the first conductive member. This can improve the adhesion between the base and the resin sealing portion.
(2) An embodiment of the present disclosure is a semiconductor device including a base having an upper surface, at least the upper surface being made of metal; one or more components that are mounted on the base with a first conductive member interposed between the one or more components and the base and include a semiconductor chip; a second conductive member that is provided on the base and contains a sintered metal or a metal powder-containing resin and on which the one or more components are not mounted; and a resin sealing portion that is provided over the base and is in contact with the base, the one or more components, and the second conductive member to seal the one or more components. The second conductive member is connected to the first conductive member and is separated from the one or more components by a distance greater than or equal to a sum of a thickness of the first conductive member between the semiconductor chip and the base and a thickness of the semiconductor chip. This can improve the adhesion between the base and the resin sealing portion.
(3) In the above (1) or (2), the first conductive member and the second conductive member may be made of a same material. This can reduce the number of types of conductive members.
(4) In any one of the above (1) to (3), at least a part of the second conductive member may overlap a bonding wire having a first end connected to one component of the one or more components when viewed in a thickness direction of the base. This can improve the adhesion between the base and the resin sealing portion in a region where the adhesion is weakened.
(5) In any one of the above (1) to (3), the semiconductor device may further include an input lead to which a high frequency signal is input and an output lead from which a high frequency signal is output. The one or more components may be provided between the input lead and the output lead. A length of at least one bonding wire of a plurality of bonding wires provided in a path electrically connecting the input lead to the output lead as viewed in a thickness direction of the base may be greater than a length of each of the one or more components in a first direction in which the input lead and the output lead are arranged. At least a part of the second conductive member may overlap the at least one bonding wire when viewed in the thickness direction of the base. This can improve the adhesion between the base and the resin sealing portion in a region where the adhesion is weakened.
(6) In any one of the above (1) to (3), the semiconductor device may further include an input lead to which a high frequency signal is input and an output lead from which a high frequency signal is output. The one or more components may be provided between the input lead and the output lead. A length of at least one bonding wire of a plurality of bonding wires provided in at least one path electrically connecting the input lead to the output lead as viewed in a thickness direction of the base may be greater than a length of each of the one or more components in a first direction in which the input lead and the output lead are arranged. At least a part of the second conductive member may be located in a second direction orthogonal to the first direction and the thickness direction of the base from the at least one bonding wire. This can improve the adhesion between the base and the resin sealing portion in a region where the adhesion is weakened.
(7) In the above (6), the at least one path includes a plurality of paths, each of the plurality of paths including the input lead, the output lead, the one or more components, and the plurality of bonding wires provided in the at least one path. The at least a part of the second conductive member is provided between the at least one bonding wire of a first path among the plurality of paths and the at least one bonding wire of a second path among the plurality of paths, the first path being positioned neighboring to the second path. This can improve the adhesion between the base and the resin sealing portion in a region where the adhesion is weakened.
(8) In any one of the above (5) to (7), the semiconductor chip may include a transistor configured to amplify the high frequency signal input to the input lead and output an amplified high frequency signal to the output lead. The at least one bonding wire may be included in a matching circuit configured to match an impedance between the input lead and the transistor, or a matching circuit configured to match an impedance between the transistor and the output lead. This can improve the adhesion between the base and the resin sealing portion in a region where the adhesion is weakened.
(9) In any one of the above (1) to (8), the second conductive member may include a constriction portion in a cross section parallel to a thickness direction of the base. This can further improve the adhesion between the base and the resin sealing portion.
(10) In any one of the above (1) to (8), the second conductive member may include a first portion that extends in the third direction on the base, and a second portion that extends in a fourth direction intersecting the third direction on the base and is provided between the first portion and the base at an intersection with the first portion. This can further improve the adhesion between the base and the resin sealing portion.
(11) An embodiment of the present disclosure is a method of manufacturing a semiconductor device. The method includes forming a first conductive member and a second conductive member on a base having an upper surface, at least the upper surface being made of metal; mounting one or more components including a semiconductor chip on the first conductive member and not mounting the one or more components on the second conductive member after the forming the first conductive member and the second conductive member; and forming a resin sealing portion over the base so as to be in contact with the base, the one or more components, and the second conductive member and seal the one or more components. The second conductive member is separated from the first conductive member or connected to the first conductive member, and separated from the one or more components by a distance greater than or equal to a sum of a thickness of the first conductive member between the semiconductor chip and the base and a thickness of the semiconductor chip. This can easily improve the adhesion between the base and the resin sealing portion.

### Details of Embodiments of the Present Disclosure

Specific examples of a semiconductor device and a method for manufacturing the same according to embodiments of the present disclosure will be described below with reference to the drawings. The present disclosure is not limited to these examples, but is defined by the claims, and is intended to include all modifications within the scope and meaning equivalent to the appended claims.

### (Semiconductor Device of First Embodiment)

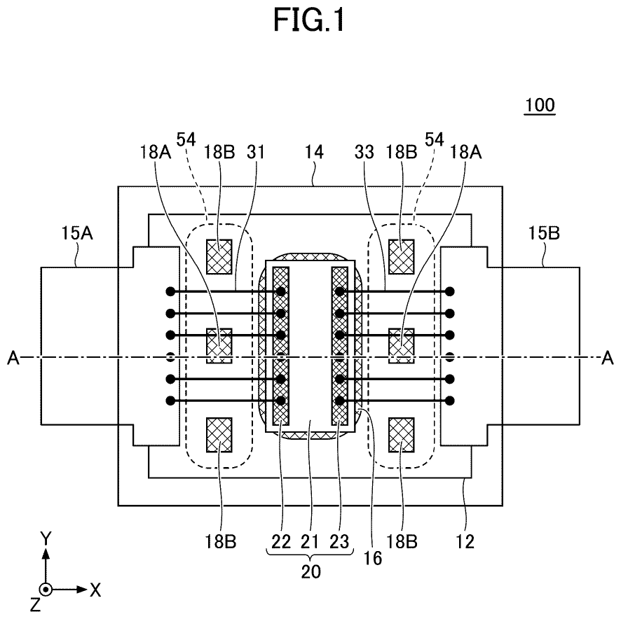

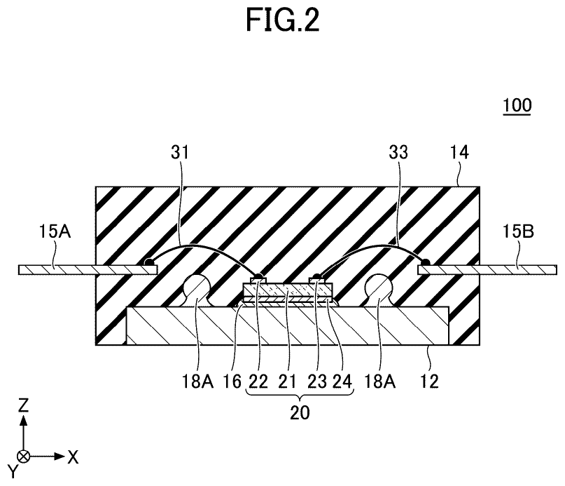

A first embodiment is an example in which a semiconductor chip is mounted as one component on the base. FIG. 1 is a plan view of a semiconductor device according to the first embodiment. In FIG. 1, a resin sealing portion 14 is illustrated in a see-through manner. FIG. 2 is a cross-sectional view taken along line A-A in FIG. 1. A thickness direction of a base 12 is defined as a Z-axis direction, an arrangement direction of leads 15A and 15B is defined as an X-axis direction, and a direction orthogonal to the X-axis direction and the Z-axis direction is defined as a Y-axis direction.

As illustrated in FIG. 1 and FIG. 2, a semiconductor device 100 according to the first embodiment includes base 12, resin sealing portion 14, leads 15A and 15B, a conductive member 16, conductive members 18A and 18B, a semiconductor chip 20, and bonding wires 31 and 33.

Base 12 functions as, for example, a heat spreader that diffuses heat generated in semiconductor chip 20. At least an upper surface of base 12 is made of metal. Semiconductor chip 20 is mounted on base 12 with conductive member 16 interposed between semiconductor chip 20 and base 12. Semiconductor chip 20 includes a substrate 21 and electrodes 22, 23, and 24. Electrodes 22 and 23 are provided on an upper surface of substrate 21, and electrode 24 is provided on a lower surface of substrate 21. Conductive member 16 bonds base 12 to electrode 24.

Resin sealing portion 14 is provided over base 12 in contact with base 12, semiconductor chip 20, and conductive members 18A and 18B to seal semiconductor chip 20. A lower surface of base 12 is exposed from resin sealing portion 14. The lower surface of base 12 may be covered with resin sealing portion 14. First ends of leads 15A and 15B are provided in resin sealing portion 14, and second ends of leads 15A and 15B are exposed from resin sealing portion 14. Bonding wire 31 electrically connects electrode 22 to a first end of lead 15A. Bonding wire 33 electrically connects electrode 23 to the first end of lead 15B. Conductive members 18A and 18B are provided on base 12, and a component such as semiconductor chip 20 is not mounted thereon. Conductive member 18A is provided between bonding wire 31 and base 12 so as to overlap bonding wire 31, and conductive member 18A is provided between bonding wire 33 and base 12 so as to overlap bonding wire 33 when viewed in the Z-axis direction. Two conductive members 18B sandwich bonding wire 31 in the Y-axis direction, and the other two conductive members 18B sandwich bonding wire 33 in the Y-axis direction.

The material of base 12 is, for example, copper, a copper-based alloy, a laminated material containing copper (for example, a copper layer, a molybdenum layer, and a copper layer), aluminum, or an aluminum alloy. The surface of base 12 may be plated with gold, for example. The material of leads 15A and 15B is a metal such as copper, a copper-based alloy or an iron-based alloy. The material of bonding wires 31 and 33 is, for example, gold, silver, copper, aluminum, or an alloy mainly containing these metals. Resin sealing portion 14 is made of, for example, an epoxy resin containing a filler. The filler is, for example, an inorganic insulating filler such as silicon oxide.

The material of conductive member 16 is, for example, a sintered metal, a metal powder-containing resin, or a solder such as gold-tin (AuSn) or gold-silicon (AuSi). The material of conductive members 18A and 18B is, for example, a sintered metal or a metal powder-containing resin. The sintered metal is obtained by sintering a paste containing metal powders of, for example, silver, copper, or gold. The components of the sintered metal are mostly silver, copper, or gold. The metal powder-containing resin is obtained by curing a resin containing metal powders. The metal powders are made of, for example, silver, copper or gold. The resin is, for example, an epoxy resin. The content of the metal powders in the metal powder-containing resin is, for example, 50% by mass to 95% by mass, or, as another example, 70% by mass to 90% by mass.

Semiconductor chip 20 includes, for example, a transistor. The transistor is, for example, a laterally diffused metal oxide semiconductor (LDMOS) or a gallium nitride high electron mobility transistor (GaN-HEMT). The transistor may be a MOS field effect transistor (MOSFET) or a bipolar transistor other than the above.

Substrate 21 is, for example, a silicon substrate, a silicon carbide substrate, a gallium nitride substrate, or a gallium arsenide substrate. Electrodes 22 to 24 contain, for example, gold, aluminum, copper, silver, nickel, or the like.

### (Manufacturing Method in First Embodiment)

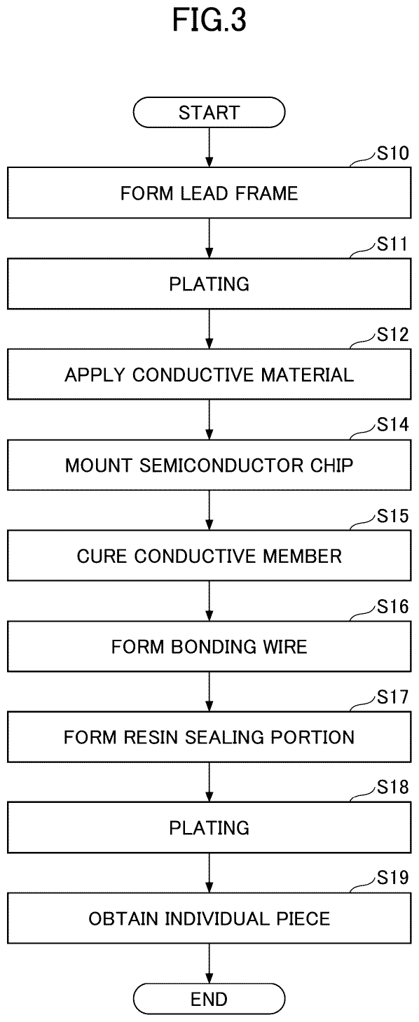

FIG. 3 is a flowchart illustrating a manufacturing method in the first embodiment. As illustrated in FIG. 3, a lead frame is formed (step S10). The lead frame includes base 12 and leads 15A and 15B. Leads 15A and 15B connect the bases 12. Next, the lead frame is subjected to plating (step S11). In the plating step, a metal having a good wettability with conductive member 16, such as a gold plating, is plated. A plating film is provided on the lead frame.

Next, conductive members 16, 18A, and 18B are applied onto base 12 (step S12). For example, a solution containing conductive members 16, 18A, and 18B is contained in a tube, and the solution is discharged from the tube in a linear stream.

Next, semiconductor chip 20 is mounted on conductive member 16 (step S14). Conductive members 16, 18A, and 18B are then cured (step S15). For example, by performing a heat treatment on base 12, a solvent in the solution containing conductive members 16, 18A, and 18B is evaporated, and conductive members 16, 18A, and 18B are cured. Through the above steps, semiconductor chip 20 is fixed onto base 12.

Subsequently, bonding wires 31 and 33 are formed (step S16). For example, a first end and a second end of bonding wire 31 are bonded to electrode 22 and lead 15A, respectively, and a first end and a second end of bonding wire 33 are bonded to electrode 23 and lead 15B, respectively. Next, resin sealing portion 14 is formed (step S17). Resin sealing portion 14 is formed by using, for example, a transfer molding method.

Plating is then performed on base 12 and portions of leads 15A and 15B that are exposed from resin sealing portion 14 (step S18). For example, the lower surface of base 12 and surfaces of leads 15A and 15B exposed from resin sealing portion 14 are plated with tin or solder. Next, leads 15A and 15B are cut to obtain individual pieces of semiconductor device 100 (step S19). Through the above steps, semiconductor device 100 according to the first embodiment is manufactured.

### Description of First Embodiment

Since semiconductor chip 20 is mounted using conductive member 16, at least the uppermost layer of base 12 is a metal layer. In order to improve the wettability of conductive member 16, the surface of base 12 may be plated with gold. Since the upper surface of base 12 is made of metal, the adhesion between base 12 and resin sealing portion 14 is weak. For this reason, in FIG. 1, in a region 54 of the upper surface of base 12 where semiconductor chip 20 and other components are not mounted, resin sealing portion 14 may peel off from base 12 due to a thermal stress caused by, for example, a difference in linear expansion coefficient between base 12 and resin sealing portion 14.

In order to suppress resin sealing portion 14 from peeling off from base 12, it is considered to reduce the area of the exposed surface of base 12. However, for example, when bonding wires 31 and 33 are made longer, the flexibility in the arrangement of semiconductor chip 20 is reduced. As described in Patent Literature 1, it is conceivable to roughen the surface of base 12. However, this needs an additional step of roughening the surface of base 12. Furthermore, when the surface roughness of the roughened surface is increased to improve the adhesion, it makes it difficult to mount semiconductor chip 20.

It is conceivable that a region of the upper surface of base 12 where semiconductor chip 20 is not mounted is roughened without roughening a region of the upper surface of base 12 where semiconductor chip 20 is mounted. However, in a case where a portion of the upper surface of base 12 is roughened before the step S12 in FIG. 3, for example, the flexibility in the arrangement of semiconductor chip 20 is reduced. In a case where a portion of the upper surface of base 12 is roughened after the step S15 in FIG. 3, the number of steps of roughening is increased, and furthermore, debris is generated due to the roughening.

When the adhesion between resin sealing portion 14 and base 12 is reduced by the plating film of base 12, it is considered that, in the step S11, plating is performed on the region of the upper surface of base 12 where semiconductor chip 20 is mounted, and plating is not performed on the region where semiconductor chip 20 is not mounted. However, the region where plating is not performed has a poor wettability with the conductive member 16, and semiconductor chip 20 cannot be mounted thereon. Thus, the flexibility in the arrangement of semiconductor chip 20 is reduced.

In the first embodiment, as a method of manufacturing semiconductor device 100, conductive members 16, 18A, and 18B are formed on base 12 as in the step S12. As in the step S14, semiconductor chip 20 is then mounted on conductive member 16 (first conductive member), and no components are mounted on conductive members 18A and 18B (second conductive member). As in the step S17, resin sealing portion 14 is formed over base 12 so as to be in contact with base 12, semiconductor chip 20, and conductive members 18A and 18B and seal semiconductor chip 20.

In semiconductor device 100, conductive members 18A and 18B are provided, and thus it is possible to improve the adhesion between resin sealing portion 14 and base 12. Conductive members 18A and 18B each contain a sintered metal or a metal powder-containing resin. Thus, conductive members 18A and 18B can be easily provided in the region of the upper surface of base 12 where semiconductor chip 20 is not mounted. Furthermore, as in the step S12 in FIG. 3, conductive members 18A and 18B can be formed in the same step as for the formation of conductive member 16. As in the step S15, conductive members 18A and 18B can be cured in the same step as in the curing of the conductive member 16. Thus, the manufacturing steps can be simplified. In addition, since conductive members 18A and 18B can be formed in the region where semiconductor chip 20 is not mounted, the flexibility in the arrangement of semiconductor chip 20 can be improved.

The material of conductive member 16 and the material of conductive members 18A and 18B may be the same or different. By using the same material for conductive member 16 and conductive members 18A and 18B, conductive member 16 and conductive members 18A and 18B can be formed using the same material in the step S12. Thus, the number of types of conductive members can be reduced.

From the viewpoint of suppressing resin sealing portion 14 from peeling off from base 12, conductive members 18A and 18B may be provided in region 54 where semiconductor chip 20 and other components are not provided. For example, in many cases, no component is provided in the regions of bonding wires 31 and 33 whose first ends are connected to semiconductor chip 20. Thus, as exemplified by conductive member 18A, at least a part of conductive member 18A can be disposed between bonding wires 31 and 33 and base 12.

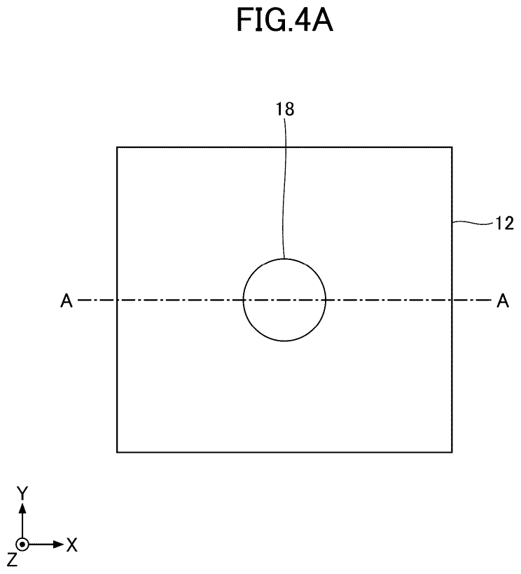

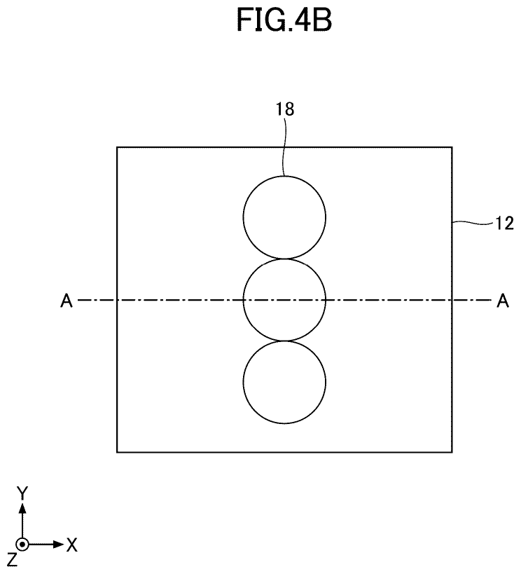

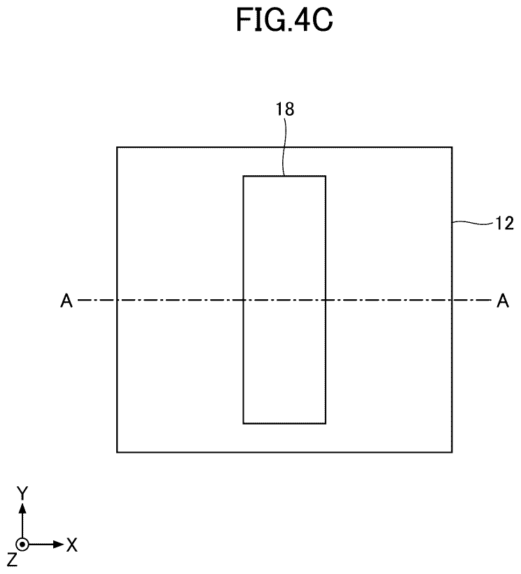

FIG. 4A to FIG. 4C are plan views of conductive member 18 in the first embodiment. As illustrated in FIG. 4A, conductive member 18 may have a dot-like planar shape. As illustrated in FIG. 4B, conductive member 18 may have a planar shape in which dots are connected to each other. As illustrated in FIG. 4C, conductive member 18 may have a linear planar shape. In the step S12, when conductive member 18 is formed by discharging a highly viscous liquid containing conductive member 18 from a tube, conductive member 18 having the planar shapes illustrated in FIG. 4A to FIG. 4C can be formed by controlling a pressure applied to the tube.

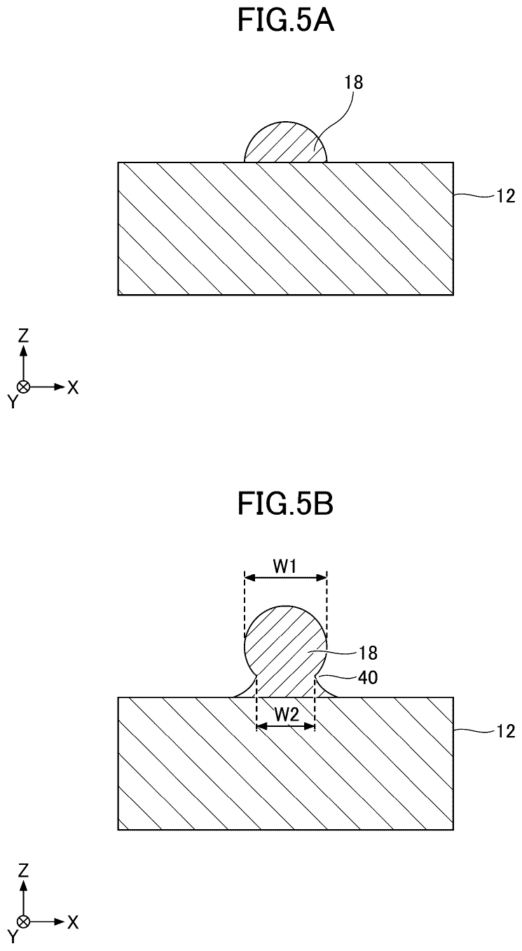

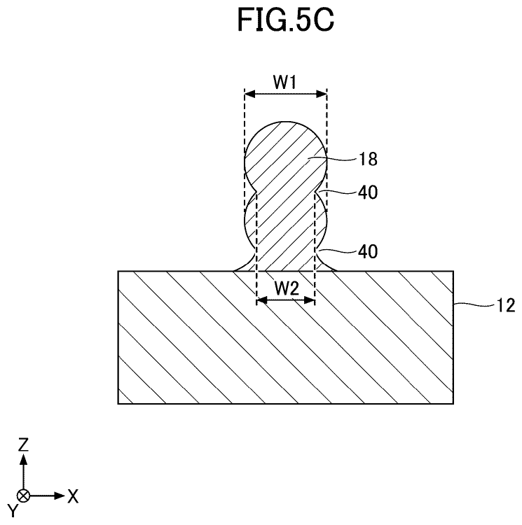

FIG. 5A to FIG. 5C are cross-sectional views of conductive member 18 in the first embodiment. FIG. 5A to FIG. 5C are cross-sectional views taken along line A-A in FIG. 4A to FIG. 4C, respectively. As illustrated in FIG. 5A, the cross-sectional shape of conductive member 18 may be a shape formed of a part of a circle or an oval, such as a semicircle. For example, when a highly viscous solution containing conductive member 18 is discharged from the tube from a position near base 12, conductive member 18 has a cross-sectional shape as illustrated in FIG. 5A.

As illustrated in FIG. 5B, the cross-sectional shape of conductive member 18 may be a shape in which a circle or an oval is connected onto a semicircle or a semioval. For example, when the highly viscous solution containing conductive member 18 is discharged from the tube from a position away from base 12 in the Z-axis direction, conductive member 18 has a cross-sectional shape as illustrated in FIG. 5B.

As illustrated in FIG. 5C, the cross-sectional shape of conductive member 18 may be a shape in which a circle or an oval is connected onto the circle or the oval illustrated in FIG. 5B. As illustrated in FIG. 5B and FIG. 5C, conductive member 18 has a constriction portion 40 in a cross section parallel to the Z-axis direction. This makes it more difficult for resin sealing portion 14 to peel off from base 12. By setting the number of constriction portions 40 in the Z-axis direction to be plural, resin sealing portion 14 is less likely to peel off from base 12.

In FIG. 5B and FIG. 5C, when a width of constriction portion 40 is denoted as W2, and a maximum width of conductive member 18 above constriction portion 40 is denoted as W1, a width W2 is less than a width W1. Resin sealing portion 14 is in contact with constriction portion 40, and thus resin sealing portion 14 is less likely to peel off from base 12. Width W2 may be 0.9 times or less width W1. From the viewpoint that conductive member 18 is not separated in the Z-axis direction due to constriction portion 40, width W2 may be 0.1 times or more width W1.

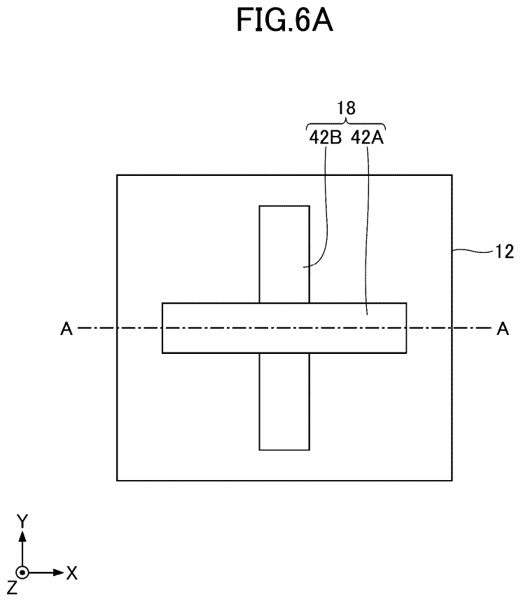

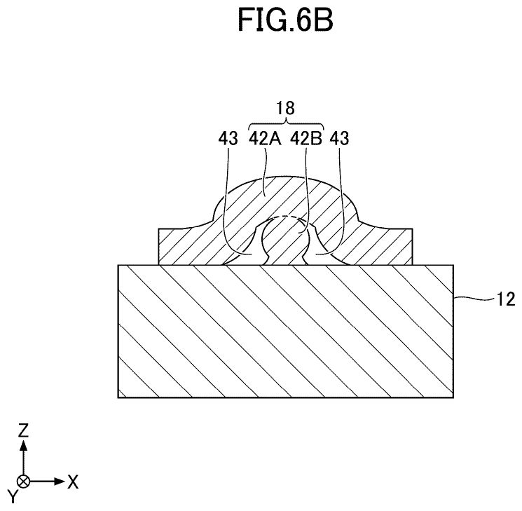

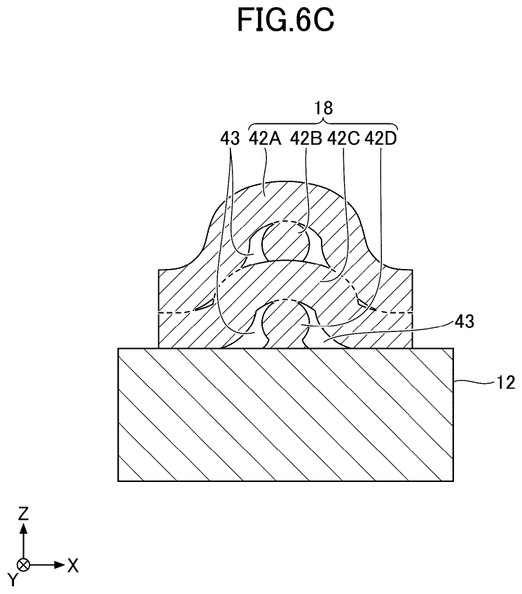

FIG. 6A is a plan view illustrating another example of conductive member 18 in the first embodiment. FIG. 6B and FIG. 6C are cross-sectional views taken along line A-A in FIG. 6A. As illustrated in FIG. 6A, conductive member 18 has linear portions 42A (first portion) and 42B (second portion) as viewed in the Z-axis direction. Portion 42A extends in the X-axis direction (third direction) on base 12. Portion 42B extends in the Y-axis direction (fourth direction intersecting the third direction) on base 12, and is provided between portion 42A and base 12 at an intersection with portion 42A. This complicates the shape of conductive member 18 at the intersection of portions 42A and 42B. For example, a space 43 is formed between portion 42A and portion 42B. Resin sealing portion 14 comes into contact with the complex shape, and thus resin sealing portion 14 is less likely to peel off from base 12.

As illustrated in FIG. 6C, conductive member 18 includes portions 42A to 42D. When viewed in the Z-axis direction, portion 42C overlaps portion 42A, and portion 42D overlaps portion 42B. Portion 42C is provided between portion 42B and base 12, and portion 42D is provided between portion 42C and base 12. This makes the shape of conductive member 18 at intersections of portions 42A and 42C with portions 42B and 42D more complex than in FIG. 6B. For example, more spaces 43 are formed than in FIG. 6B. As a result, resin sealing portion 14 comes into contact with a complex shape, and thus resin sealing portion 14 is less likely to peel off from base 12.

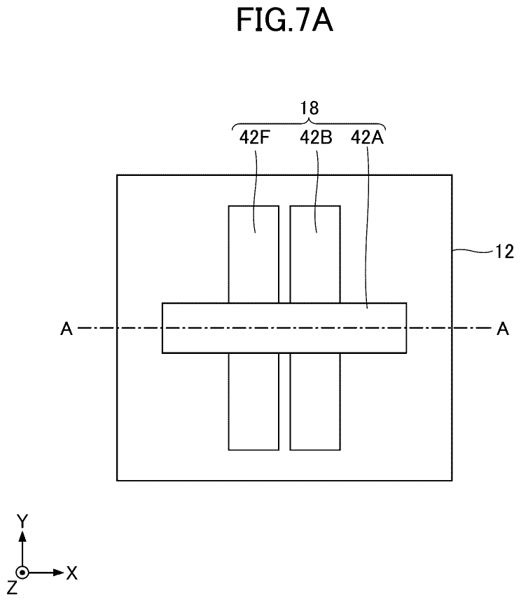

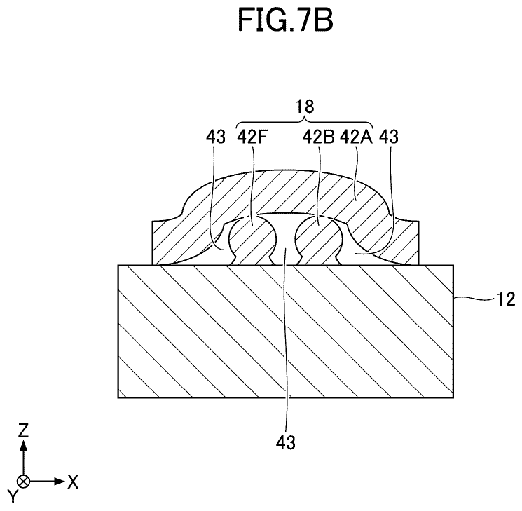

FIG. 7A is a plan view illustrating still another example of conductive member 18 in the first embodiment. FIG. 7B is a cross-sectional view taken along line A-A in FIG. 7A. As illustrated in FIG. 7A, conductive member 18 includes linear portions 42A, 42B, and 42F. Portion 42F extends substantially parallel to portion 42B and is provided between portion 42A and base 12 at an intersection with portion 42A. As described above, the portions intersecting portion 42A may be plural portions 42B and 42F. This makes the number of intersections of portion 42A plural. Thus, the shape of conductive member 18 becomes complex. For example, spaces 43 are formed between portion 42A and portion 42B and between portion 42A and portion 42F. Resin sealing portion 14 comes into contact with the complex shape, and this makes more difficult for resin sealing portion 14 to peel off from base 12. The example in which portions 42A to 42D and 42F are linear when viewed in the Z-axis direction has been described, but portions 42A to 42D and 42F may be curved when viewed in the Z-axis direction.

### Second Embodiment

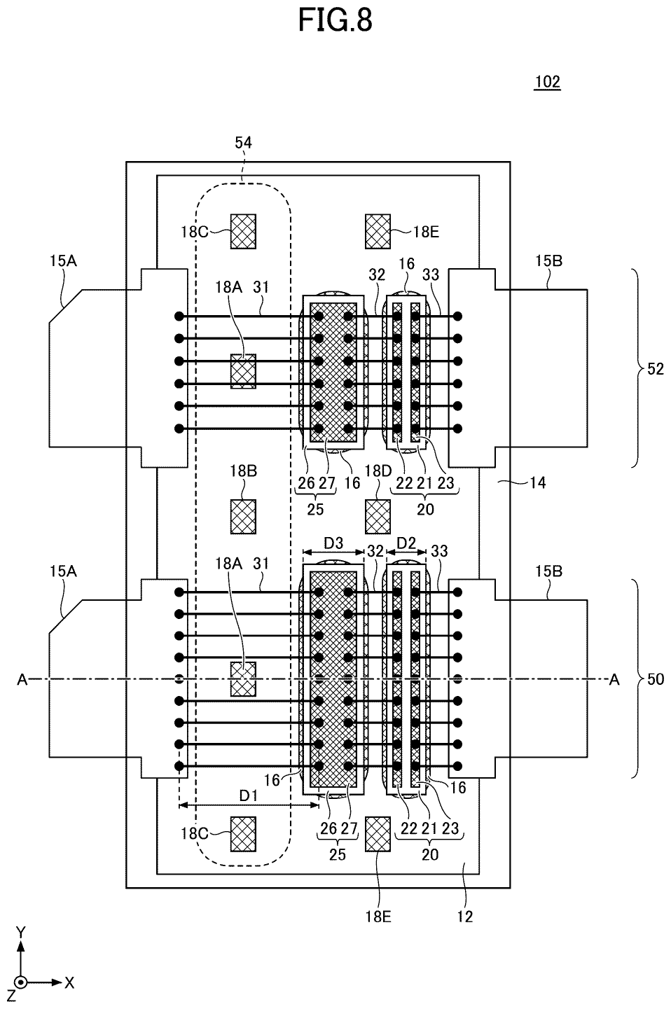

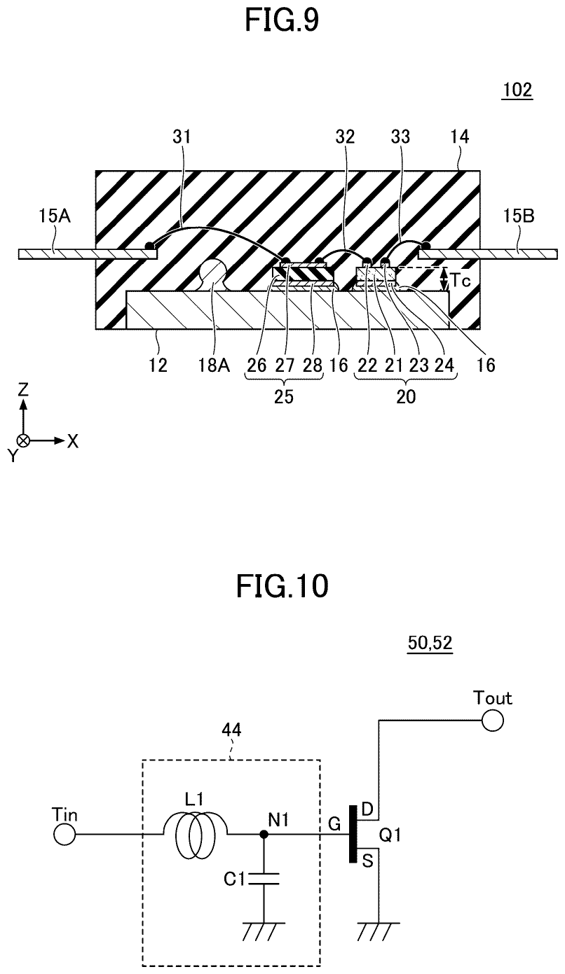

The second embodiment is an example in which one or more components mounted on base 12 include a semiconductor chip for a high frequency signal. FIG. 8 is a plan view of a semiconductor device according to the second embodiment. FIG. 9 is a cross-sectional view taken along line A-A in FIG. 8. FIG. 10 is a circuit diagram of paths 50 and 52 in the second embodiment.

As illustrated in FIG. 8 and FIG. 9, a semiconductor device 102 includes two paths 50 and 52. Each of paths 50 and 52 includes semiconductor chip 20, a passive chip 25, bonding wires 31 to 33, and leads 15A and 15B. Passive chip 25 and semiconductor chip 20 are arranged in the X-axis direction between leads 15A and 15B.

Semiconductor chip 20 includes substrate 21 and electrodes 22 to 24. Electrodes 22 and 23 are provided on substrate 21, and electrode 24 is provided under substrate 21. Passive chip 25 includes a substrate 26 and electrodes 27 and 28. Electrode 27 is provided on substrate 26, and electrode 28 is provided under substrate 26. Electrodes 24 and 28 are bonded onto base 12 with conductive member 16 interposed between electrodes 24 and 28 and base 12. Thus, base 12 is electrically connected to electrodes 24 and 28 via conductive member 16 and is short-circuited. Substrate 26 is a dielectric substrate made of, for example, alumina or barium titanate. Substrate 26, and electrodes 27 and 28 sandwiching substrate 26 function as a capacitor.

Bonding wire 31 electrically connects lead 15A to electrode 27. Bonding wire 32 electrically connects electrode 27 to electrode 22. Bonding wire 33 electrically connects electrode 23 to lead 15B.

Conductive member 18A is provided between bonding wire 31 and base 12 in the Z-axis direction. Conductive member 18B is provided between bonding wire 31 of path 50 and bonding wire 31 of path 52. Conductive members 18C and 18B are provided so as to sandwich bonding wire 31 of path 50 or sandwich bonding wire 31 of path 52. A conductive member 18D is provided between a region of path 50 other than bonding wire 31 and a region of path 52 other than bonding wire 31. Conductive member 18D and a conductive member 18E are provided so as to sandwich the region of path 50 other than bonding wire 31 or sandwich the region of path 52 other than bonding wire 31.

As illustrated in FIG. 10, paths 50 and 52 each include an input terminal Tin, an output terminal Tout, an inductor L1, a capacitor C1, and a transistor Q1. The first end of inductor L1 is electrically connected to a node N1, and the second end of inductor L1 is electrically connected to input terminal Tin. The first end of capacitor C1 is electrically connected to node N1, and the second end is electrically connected to a reference potential such as ground. Transistor Q1 is an FET, and has a source S electrically connected to a reference potential and a gate G electrically connected to node N1. A drain D is electrically connected to output terminal Tout.

A matching circuit 44 is a low-pass filter type matching circuit, and includes inductor L1 and capacitor C1. Matching circuit 44 matches an impedance as viewed from input terminal Tin to matching circuit 44 with an impedance as viewed from matching circuit 44 to transistor Q1. A high frequency signal input to input terminal Tin is input to gate G of transistor Q1 via matching circuit 44. The high frequency signal amplified by transistor Q1 is output from drain D to output terminal Tout. For example, when semiconductor device 102 is used for base stations in mobile communication, the frequency of the high-frequency signal is from 0.5 GHz to 20 GHz.

Input terminal Tin and output terminal Tout in FIG. 10 correspond to leads 15A and 15B in FIG. 8 and FIG. 9, respectively. Inductor L1 in FIG. 10 corresponds to bonding wire 31 in FIG. 8 and FIG. 9. Capacitor C1 in FIG. 10 corresponds to passive chip 25 in FIG. 8 and FIG. 9. Transistor Q1 in FIG. 10 corresponds to semiconductor chip 20 in FIG. 8 and FIG. 9. Gate G, drain D and source S correspond to electrodes 22, 23 and 24 in FIG. 9, respectively. The reference potential in FIG. 10 corresponds to base 12 of FIG. 8 and FIG. 9.

As illustrated in FIG. 8 to FIG. 10, when matching circuit 44 is provided in semiconductor device 102, bonding wire 31 is lengthened to function as inductor L1. For example, a length D1 of bonding wire 31 as viewed in the Z-axis direction is greater than length D2 of semiconductor chip 20 in the X-axis direction and length D3 of passive chip 25 in the X-axis direction. In such a case, no other component is mounted in region 54 between lead 15A and passive chip 25, and region 54 in which no component is mounted is widened. Thus, conductive members 18A to 18C are provided. When paths 50 and 52 are provided far from each other, a conductive member 18D is provided. When paths 50 and 52 are provided far from the edge of base 12, conductive member 18E is provided. This can suppress resin sealing portion 14 from peeling off from base 12.

### First Modification of Second Embodiment

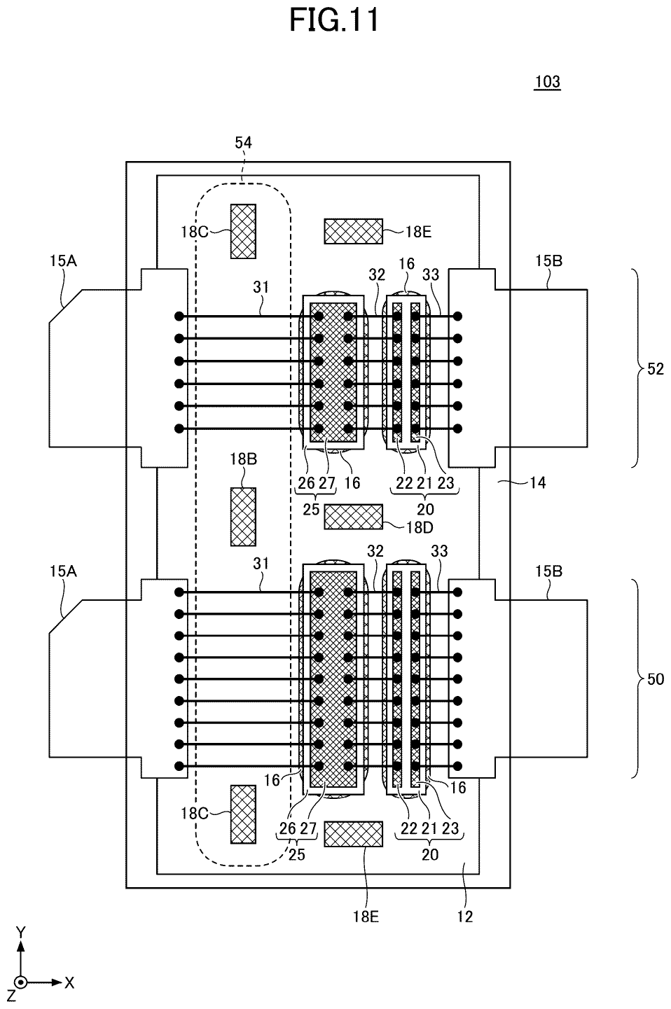

FIG. 11 is a plan view of a semiconductor device according to a first modification of the second embodiment. As illustrated in FIG. 11, conductive member 18A is not provided in a semiconductor device 103 of the first modification of the second embodiment. When conductive member 18A is provided, high-frequency characteristics of bonding wire 31 may change. In such a case, conductive member 18A may not be provided. The other configurations are the same as those of the second embodiment, and the description thereof will be omitted.

### Second Modification of Second Embodiment

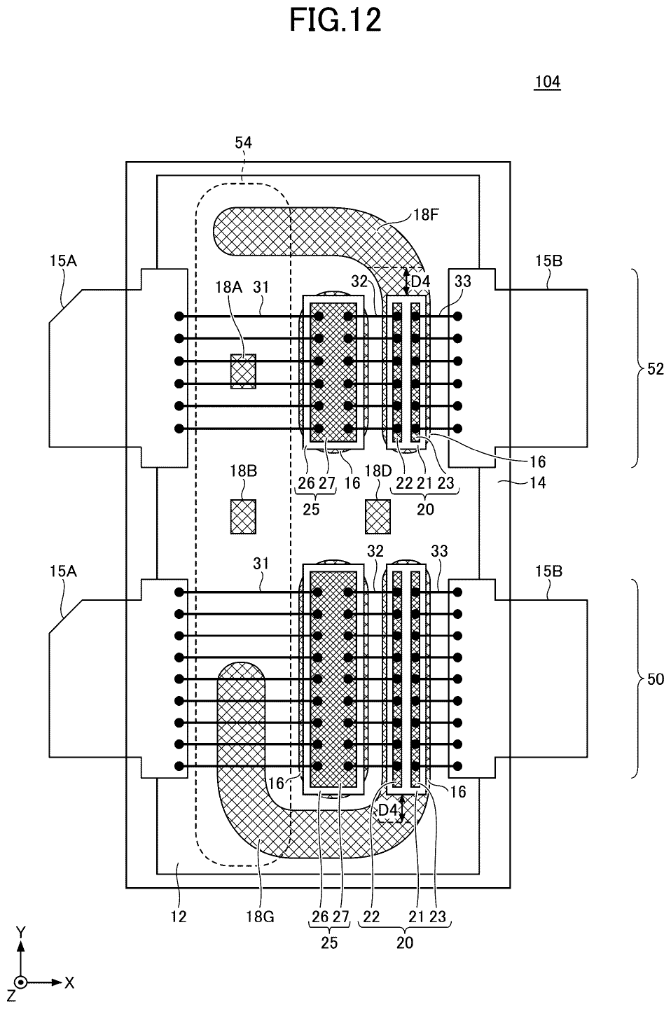

FIG. 12 is a plan view of a semiconductor device according to a second modification of the second embodiment. As illustrated in FIG. 12, in a semiconductor device 104 of the second modification of the second embodiment, a conductive member 18F is connected to conductive member 16 on which semiconductor chip 20 of path 52 is mounted. A conductive member 18G is connected to conductive member 16 on which semiconductor chip 20 of path 50 is mounted. Conductive member 18F extends to the outside of passive chip 25 and bonding wire 31 in a positive direction along the Y-axis. Conductive member 18G extends to the outside of passive chip 25 and bonding wire 31 in a negative direction along the Y-axis, and further extends to a position between bonding wire 31 and base 12 in the Z-axis direction.

Conductive members 18F and 18G can be formed by continuously discharging the solution from the tube subsequently to conductive member 16 in the step S12 in FIG. 3. In FIG. 9, a total thickness of a thickness of conductive member 16 between semiconductor chip 20 and base 12 and a thickness of semiconductor chip 20 is denoted as Tc. When semiconductor chip 20 and passive chip 25 are mounted using conductive member 16, an amount of protrusion of conductive member 16 from semiconductor chip 20 and passive chip 25 is smaller than thickness Tc. Thus, distance D4 from semiconductor chip 20 to conductive member 18F and to conductive member 18G is set to be greater than or equal to thickness Tc. Conductive member 18F is provided instead of conductive members 18C and 18E of the second embodiment. Conductive member 18G is provided instead of conductive members 18A, 18C, and 18E of the second embodiment. The other configurations are the same as those of the second embodiment, and the description thereof will be omitted.

### Third Modification of Second Embodiment

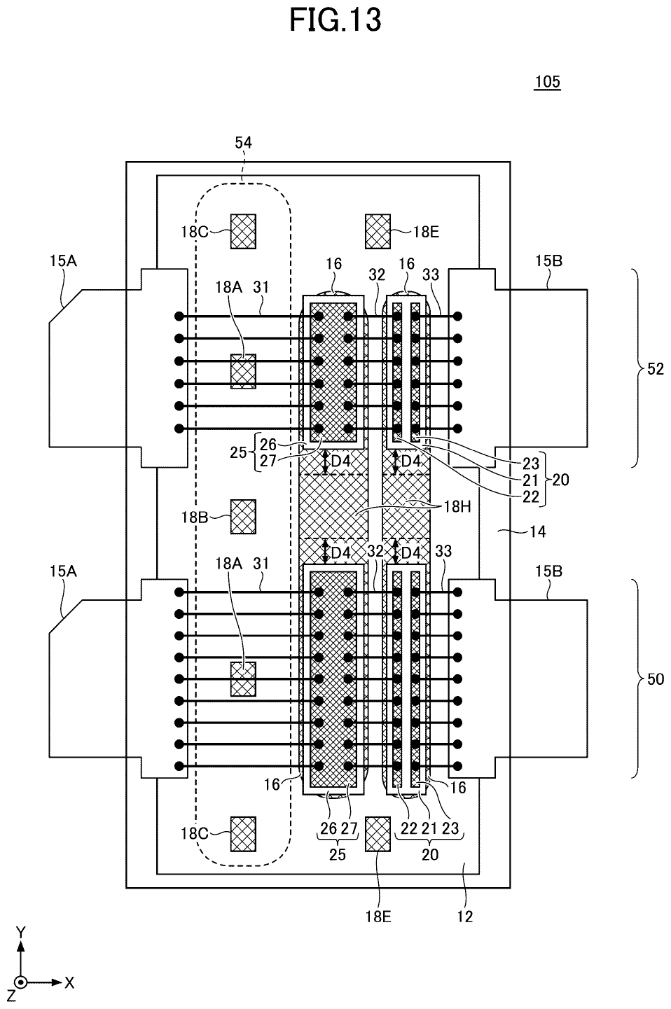

FIG. 13 is a plan view of a semiconductor device according to a third modification of the second embodiment. As illustrated in FIG. 13, in a semiconductor device 105 of the third modification of the second embodiment, a conductive member 18H is provided to be connected between conductive member 16 on which semiconductor chip 20 of path 50 is mounted and conductive member 16 on which semiconductor chip 20 of path 52 is mounted. Another conductive member 18H is provided to be connected between conductive member 16 on which passive chip 25 of path 50 is mounted and conductive member 16 on which passive chip 25 of path 52 is mounted. Distance D4 from conductive member 18H to semiconductor chip 20 and to passive chip 25 is greater than or equal to thickness Tc. Conductive member 18H is provided instead of conductive member 18D of the second embodiment. The other configurations are the same as those of the second embodiment, and the description thereof will be omitted.

As in the second modification and the third modification of the second embodiment, conductive members 18F to 18H are connected to conductive member 16 and are separated from semiconductor chip 20 and passive chip 25 by a distance of thickness Tc or more. Thus, in the step S12 in FIG. 3, by continuously discharging the solution for forming conductive members 18F to 18H subsequently to the solution for forming conductive members 16, conductive members 18F to 18H can be formed. Distance D4 may be 1.5 mm or more, or may be 2 mm or more. Distance D4 may be 1.5 times or more, or 2 times or more thickness Tc. When distance D4 is too long, base 12 becomes large. From this viewpoint, distance D4 may be equal to or less than 5 mm. Distance D4 may be 5 times or less thickness Tc.

### Fourth Modification of Second Embodiment

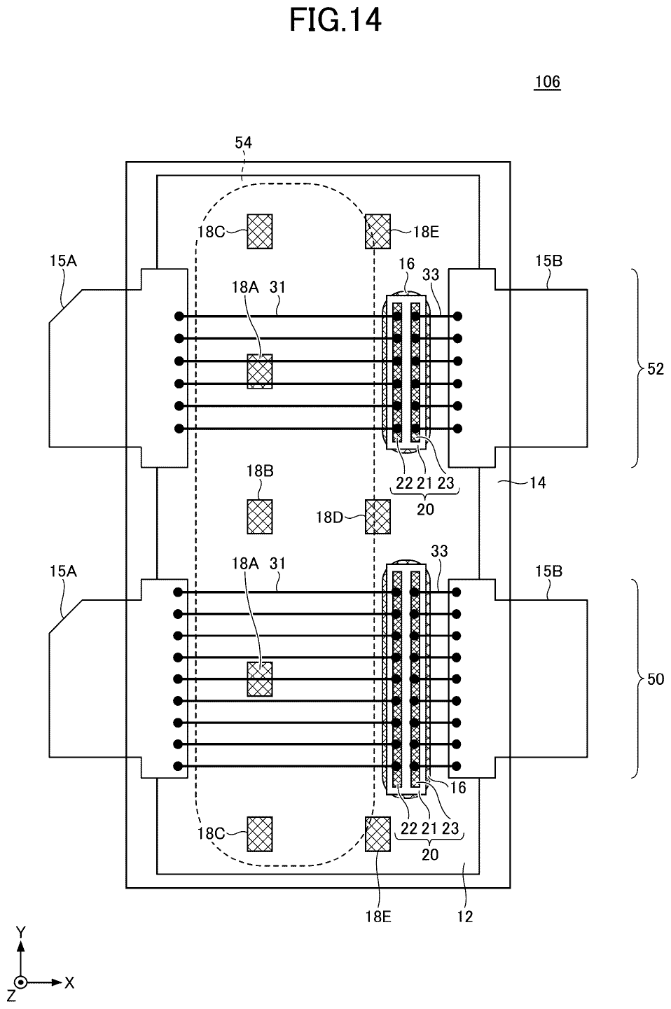

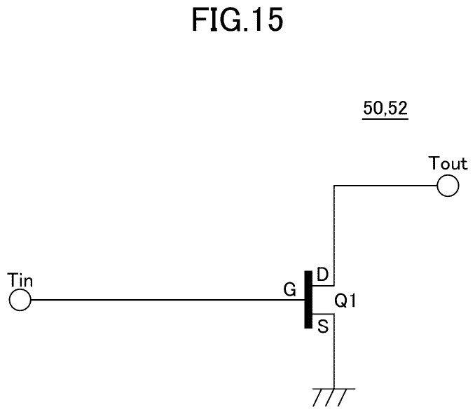

FIG. 14 is a plan view of a semiconductor device according to a fourth modification of the second embodiment. FIG. 15 is a circuit diagram of paths 50 and 52 in the fourth modification of the second embodiment. As illustrated in FIG. 14, a semiconductor device 106 of the fourth modification of the second embodiment is not provided with passive chip 25. Bonding wire 31 electrically connects lead 15A to electrode 22.

As illustrated in FIG. 15, paths 50 and 52 of semiconductor device 106 do not include matching circuits. For example, when the frequency of a high-frequency signal is from 1 MHz to 1 GHz, there is no need to provide a matching circuit for matching an impedance in semiconductor device 106. When a planar area of base 12 is reduced, heat dissipation property is deteriorated. When the planar area of base 12 is increased, bonding wire 31 is lengthened. Bonding wire 33 may be lengthened, but in order to improve high frequency characteristics, bonding wire 33 to which an amplified high frequency signal is output may be shortened. Accordingly, region 54 between lead 15A and semiconductor chip 20 in FIG. 14 is widened. Thus, conductive members 18A to 18C are provided in region 54. The other configurations are the same as those of the second embodiment, and the description thereof will be omitted.

### Fifth Modification of Second Embodiment

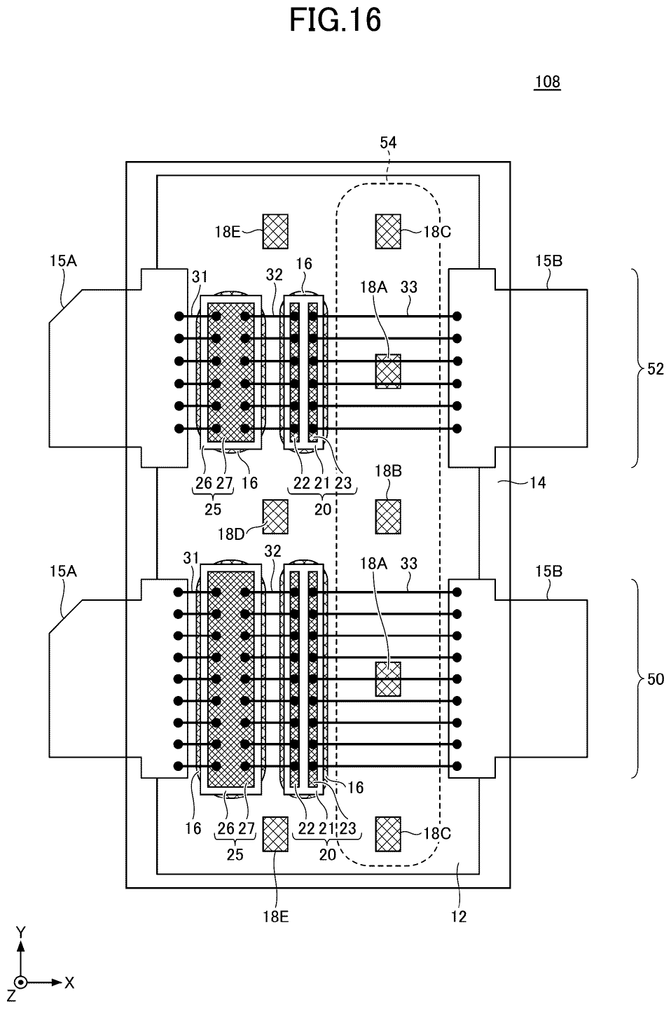

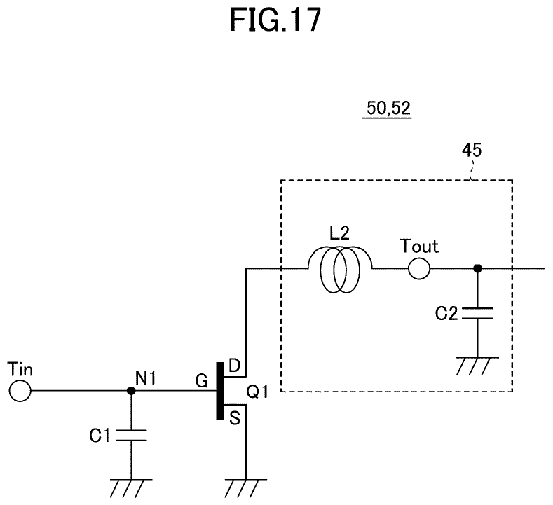

FIG. 16 is a plan view of a semiconductor device according to a fifth modification of the second embodiment. FIG. 17 is a circuit diagram of paths 50 and 52 in the fifth modification of the second embodiment. As illustrated in FIG. 16, in a semiconductor device 108 of the fifth modification of the second embodiment, bonding wire 33 is longer than bonding wire 31. Conductive member 18A is provided between bonding wire 33 and base 12. Conductive member 18B is provided between bonding wire 33 of path 50 and bonding wire 33 of path 52 in the Y-axis direction. Conductive members 18B and 18C sandwich bonding wire 33 in the Y-axis direction.

As illustrated in FIG. 17, paths 50 and 52 of semiconductor device 108 each include input terminal Tin, output terminal Tout, capacitor C1, an inductor L2, and transistor Q1. Node N1 is electrically connected to input terminal Tin. A first end of inductor L2 is connected to the drain of transistor Q1, and a second end of inductor L2 is electrically connected to output terminal Tout. Outside semiconductor device 108, a capacitor C2 is shunt-connected to output terminal Tout. A matching circuit 45 includes inductor L2 and capacitor C2. Matching circuit 45 matches an impedance as viewed from drain D to matching circuit 45 with an impedance as viewed from matching circuit 45 to a subsequent stage. Inductor L2 in FIG. 17 corresponds to bonding wire 33 in FIG. 16. Bonding wire 33 is lengthened to increase an inductance of inductor L2. Accordingly, region 54 between semiconductor chip 20 and lead 15B in FIG. 16 is widened. Thus, conductive members 18A to 18C are provided in region 54. The other configurations are the same as those of the second embodiment.

### Sixth Modification of Second Embodiment

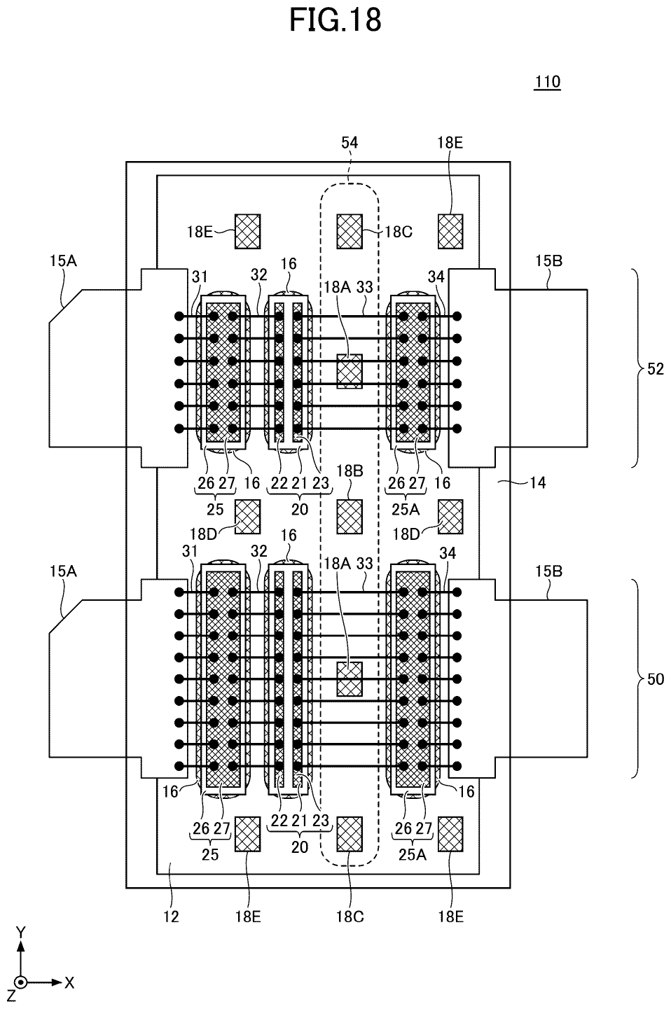

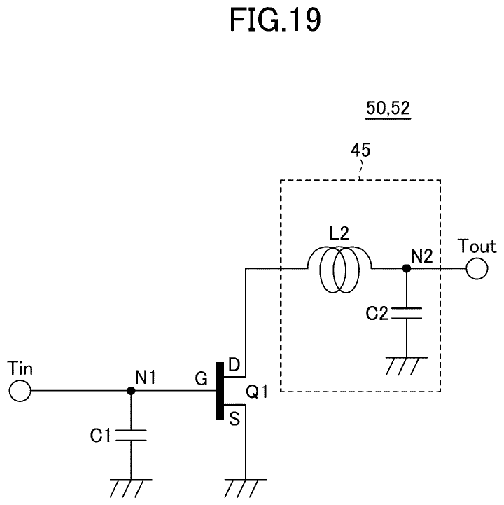

FIG. 18 is a plan view of a semiconductor device according to a sixth modification of the second embodiment. FIG. 19 is a circuit diagram of paths 50 and 52 in the sixth modification of the second embodiment. As illustrated in FIG. 18, in a semiconductor device 110 of the sixth modification of the second embodiment, a passive chip 25A is mounted, in paths 50 and 52, on base 12 between semiconductor chip 20 and lead 15B in the X-axis direction with conductive member 16 interposed between base 12 and semiconductor chip 20. Passive chip 25A includes substrate 26 and electrodes 27 and 28, and has the same structure as passive chip 25. Bonding wire 33 electrically connects electrode 23 of semiconductor chip 20 to electrode 27 of passive chip 25A. A bonding wire 34 electrically connects electrode 27 of passive chip 25A to lead 15B.

As illustrated in FIG. 19, paths 50 and 52 of semiconductor device 110 each include capacitor C2. A first end of capacitor C2 is electrically connected to node N2, and a second end is electrically connected to the reference potential. A first end of inductor L2 is electrically connected to drain D, and a second end is electrically connected to node N2. Node N2 is electrically connected to output terminal Tout. Capacitor C2 in FIG. 19 corresponds to passive chip 25A in FIG. 18. As described above, in the sixth modification of the second embodiment, capacitor C2 provided outside in the fifth modification of the second embodiment is provided in semiconductor device 110. Bonding wire 33 corresponding to inductor L2 in FIG. 18 is lengthened. Accordingly, region 54 between semiconductor chip 20 and passive chip 25A is widened. Thus, conductive members 18A to 18C are provided in region 54. The other configurations are the same as those of the fifth modification of the second embodiment.

In a semiconductor device for a high frequency signal as in the second embodiment and its modifications, one or more components such as semiconductor chip 20 and passive chips 25 and 25A are provided between lead 15A (input lead) to which a high frequency signal is input and lead 15B (output lead) from which a high frequency signal is output. A plurality of bonding wires 31 to 34 are provided in paths 50 and 52 for electrically connecting lead 15A to lead 15B. As illustrated in FIG. 8, length D1 of at least one bonding wire 31 of bonding wires 31 to 33 as viewed in the Z-axis direction is greater than each of length D2 of semiconductor chip 20 in the X-axis direction (direction in which leads 15A and 15B are arranged) and length D3 of passive chip 25 in the X-axis direction. In this case, region 54 is widened in the X-axis direction, and resin sealing portion 14 tends to easily peel off from base 12. Thus, conductive member 18A is provided between bonding wire 31 and base 12. This can suppress resin sealing portion 14 from peeling off from base 12.

Conductive members 18B and 18C are provided so as to be located in the Y-axis direction (the second direction orthogonal to the first direction and the thickness direction of the base) from bonding wire 31. This can suppress resin sealing portion 14 from peeling off from base 12. Length D1 of bonding wire 31 may be 1.5 times or more, or 2 times or more lengths D2 and D3. Length D1 may be 10 times or less lengths D2 and D3.

A plurality of paths 50 and 52 are provided, each including leads 15A and 15B, semiconductor chip 20, passive chip 25, and bonding wires 31 to 33. In this case, no component is mounted between bonding wire 31 of path 50 and bonding wire 31 of path 52. For this reason, resin sealing portion 14 tends to easily peel off from base 12. Thus, conductive member 18B is provided between bonding wires 31 of neighboring paths 50 and 52 among the plurality of paths. This can suppress resin sealing portion 14 from peeling off from base 12.

Semiconductor chip 20 includes transistor Q1 that amplifies a high frequency signal input to lead 15A and outputs the amplified high frequency signal to lead 15B. In this case, as in the second embodiment, the inductance of inductor L1 of matching circuit 44 for matching the impedance between lead 15A and transistor Q1 is increased. Thus, bonding wire 31 corresponding to inductor L1 is lengthened. Accordingly, region 54 is widened. Thus, by providing at least one of conductive members 18A to 18C, it is possible to suppress resin sealing portion 14 from peeling off from base 12.

As in the fifth modification and sixth modification of the second embodiment, the inductance of inductor L2 included in matching circuit 45 for matching the impedance between transistor Q1 and lead 15B is increased. Thus, bonding wire 33 corresponding to inductor L2 is lengthened. Accordingly, region 54 is widened. Thus, by providing at least one of conductive members 18A to 18C, it is possible to suppress resin sealing portion 14 from peeling off from base 12.

In the second embodiment and its modifications, the example having two paths 50 and 52 has been described, but the number of paths may be one, or may be three or more.

From the viewpoint of improving the adhesion between resin sealing portion 14 and base 12, each of the maximum widths of conductive members 18A to 18G in the X-axis direction and the Y-axis direction may be 0.1 mm or more, or may be 0.2 mm or more. From the viewpoint of reducing conductive member 18, each of the maximum widths of conductive member 18 in the X-axis direction and the Y-axis direction may be 20 mm or less, and may be 1 mm or more. The number of conductive members 18 may be one. The number of conductive members 18 may be greater than the number of components mounted on base 12.

It should be understood that the embodiments disclosed herein are merely illustrative and non-restrictive in all respects. The scope of the present disclosure is defined by the claims, not in the sense described above, and is intended to include all modifications within the scope and meaning equivalent to the claims.

What is claimed is:

1. A semiconductor device comprising:
a base having an upper surface, at least the upper surface being made of metal;
one or more components mounted on the base with a first conductive member interposed between the one or more components and the base, the one or more components including a semiconductor chip;
a second conductive member provided on the base and containing a sintered metal or a metal powder-containing resin, the one or more components not being mounted on the second conductive member;
a resin sealing portion provided over the base, the resin sealing portion being in contact with the base, the one or more components, and the second conductive member to seal the one or more components,
wherein the second conductive member is separated from the first conductive member.

2. A semiconductor device comprising:
a base having an upper surface, at least the upper surface being made of metal;
one or more components mounted on the base with a first conductive member interposed between the one or more components and the base, the one or more components including a semiconductor chip;
a second conductive member provided on the base and containing a sintered metal or a metal powder-containing resin, the one or more components not being mounted on the second conductive member;
a resin sealing portion provided over the base, the resin sealing portion being in contact with the base, the one or more components, and the second conductive member to seal the one or more components,
wherein the second conductive member is connected to the first conductive member and is separated from the one or more components by a distance greater than or equal to a sum of a thickness of the first conductive member between the semiconductor chip and the base and a thickness of the semiconductor chip.

3. The semiconductor device according to claim 1, wherein the first conductive member and the second conductive member are made of a same material.

4. The semiconductor device according to claim 1, wherein at least a part of the second conductive member overlaps a bonding wire having a first end connected to one component of the one or more components when viewed in a thickness direction of the base.

5. The semiconductor device according to claim 1, further comprising:
an input lead to which a high frequency signal is input; and
an output lead from which a high frequency signal is output,
wherein the one or more components are provided between the input lead and the output lead, and a length of at least one bonding wire of a plurality of bonding wires provided in a path electrically connecting the input lead to the output lead as viewed in a thickness direction of the base is greater than a length of each of the one or more components in a first direction in which the input lead and the output lead are arranged, and
wherein at least a part of the second conductive member overlaps the at least one bonding wire when viewed in the thickness direction of the base.

6. The semiconductor device according to claim 1, further comprising:
an input lead to which a high frequency signal is input; and
an output lead from which a high frequency signal is output,
wherein the one or more components are provided between the input lead and the output lead, and a length of at least one bonding wire of a plurality of bonding wires provided in at least one path electrically connecting the input lead to the output lead as viewed in a thickness direction of the base is greater than a length of each of the one or more components in a first direction in which the input lead and the output lead are arranged, and
wherein at least a part of the second conductive member is located in a second direction orthogonal to the first direction and the thickness direction of the base from the at least one bonding wire.

7. The semiconductor device according to claim 6, wherein the at least one path includes a plurality of paths, each of the plurality of paths including the input lead, the output lead, the one or more components, and the plurality of bonding wires provided in the at least one path, and
the at least the part of the second conductive member is provided between the at least one bonding wire of a first path among the plurality of paths and the at least one bonding wire of a second path among the plurality of paths, the first path being positioned neighboring to the second path.

8. The semiconductor device according to claim 5, wherein the semiconductor chip includes a transistor configured to amplify the high frequency signal input to the input lead and output an amplified high frequency signal to the output lead, and
the at least one bonding wire is included in a matching circuit configured to match an impedance between the input lead and the transistor, or a matching circuit configured to match an impedance between the transistor and the output lead.

9. The semiconductor device according to claim 1, wherein the second conductive member includes a constriction portion in a cross section parallel to a thickness direction of the base.

10. The semiconductor device according to claim 1, wherein the second conductive member includes a first portion extending in a third direction on the base, and a second portion extending in a fourth direction intersecting the third direction on the base and provided between the first portion and the base.

11. A method of manufacturing a semiconductor device, the method comprising:
forming a first conductive member and a second conductive member on a base having an upper surface, at least the upper surface being made of metal;
after the forming of the first conductive member and the second conductive member, mounting one or more components including a semiconductor chip on the first conductive member, and not mounting the one or more components on the second conductive member;
forming a resin sealing portion over the base so as to be in contact with the base, the one or more components, and the second conductive member and seal the one or more components,
wherein the second conductive member is separated from the first conductive member or connected to the first conductive member, and separated from the one or more components by a distance greater than or equal to a sum of a thickness of the first conductive member between the semiconductor chip and the base and a thickness of the semiconductor chip.
